(19) United States
(12) Patent Application Publication
(10) Pub. No.: US 2010/0182827 A1
(43) Pub. Date: Jul. 22, 2010

(54) High Margin Multilevel Phase-Change Memory via Pulse Width Programming

(76) Inventors: Sergey Kostylev, Bloomfield Hills, MI (US); Tyler Lowrey, Rochester Hills, MI (US)

Correspondence Address: Kevin L. Bray;OVONYX, INC., 2956 Waterview Drive, Rochester Hills, MI, 48309, US

(21) Appl. No.: 12/357,781

(22) Filed: Jan. 22, 2009

(51) Int. Cl. G11C 11/00

(52) U.S. Cl. 365/163; 365/148

(57) ABSTRACT

An electronic device and method of programming for binary and multilevel memory operation. The active material of the device is a phase-change material. The method includes utilization of the pulse duration of electrical pulses as a programming variable to program a phase-change device to two or more memory states that differ in the relative proportion and/or spatial arrangement of crystalline and amorphous phase regions. Pulse width programming, in conjunction with a device electrical contact having a resistivity within a particular range, enables fine control over the crystalline-amorphous phase-change process by facilitating control over the spatial distribution of thermal energy produced by Joule heating. The degree of control over the phase-change process enables reliable multilevel memory operation by providing for reproducible programming of memory states that are well-resolved in both resistance and programming variable.

### FIELD OF INVENTION

This invention relates to the programming of variable resistance memory materials. More particularly, this invention relates to the programming of phase-change memory materials for multilevel operation. Most particularly, this invention relates to programming reliability of multilevel phase-change memory devices and the use of programming pulse width at particular currents to provide greater margin in the programming current required to achieve the individual states in a multilevel memory device.

### BACKGROUND OF THE INVENTION

Variable resistance materials are promising active materials for next-generation electronic storage and computing devices. The central feature of a variable resistance material is its ability to adopt two or more distinguishable states that differ in electrical resistance. A variable resistance material can be programmed back and forth between the distinguishable states by providing energy or power. The applied energy or power induces an internal chemical, electronic, or physical transformation of the material that manifests itself as a persistent change in the resistance of the material. The different resistance states can be used as memory states to store or process data.

Phase change materials are a promising class of variable resistance materials. A phase change material is a material that is capable of undergoing a transformation, preferably reversible, between two or more distinct structural states. The distinct structural states may be distinguished on the basis of, for example, crystal structure, atomic arrangement, order or disorder, fractional crystallinity, relative proportions of two or more different structural states, or a physical (e.g. electrical, optical, magnetic, mechanical) or chemical property. In a common embodiment, the two or more distinct structural states include differing proportions of crystalline phase regions and amorphous phase regions of the phase change material, where the phase-change material is reversibly transformable between the different structural states. In the crystalline state, the phase change material has lower resistivity; while in the amorphous state, it has higher resistivity. Continuous variations in resistivity over a wide range can be achieved through control of the relative proportions of crystalline phase regions and amorphous phase regions in a volume of phase-change material. Reversibility of the transformations between structural states permits reuse of the material over multiple cycles of operation. In other embodiments, the two or more distinct structural states may include different proportions of several amorphous phases that differ in conductivity or different proportions of several crystalline phases that differ in conductivity, or combinations of any of the foregoing.

Typically, a variable resistance device is fabricated by placing the active variable resistance material, such as a phase change material, between two electrodes. Operation of the device is effected by providing an electrical signal between the two electrodes and across the active material. In a common application, phase-change materials may be used as the active material of a memory device, where distinct data values are associated with the different structural states and each data value corresponds to a distinct resistance or resistivity of the phase-change material. The different structural states employed in memory operation may also be referred to herein as memory states or resistance states of the phase-change material. Write operations in a phase-change memory device, which may also be referred to herein as programming operations, apply electric pulses to the phase-change material to alter its structural state to a target state having the resistance associated with the intended data value. Read operations are performed by providing current or voltage signals across the two electrodes to measure the resistance. The energy of the read signal is sufficiently low to prevent disturbance of the state of the phase-change material.

Presently, most phase-change memory devices are operated in binary mode. In binary mode, the memory is operated between two structural states. To improve read margin and minimize read error, the two structural states for binary operation are normally selected to maximize the resistance contrast between the states. The range of resistance values of a phase-change material is bounded by a set state having a set resistance and a reset state having a reset resistance. The set state is a low resistance structural state whose electrical properties are controlled primarily by the more conductive (e.g. crystalline) portion of the phase-change material and the reset state is a high resistance structural state whose electrical properties are controlled primarily by the more resistive (e.g. amorphous) portion of the phase-change material. The set state and reset state are most commonly employed in binary operation and may be associated with the conventional binary “0” and “1” states.

In order to expand the commercial opportunities for phase-change memory, it is desirable to identify new phase-change compositions, device structures, and methods of programming that lead to improved performance. A key performance metric for memory devices is storage density, which is a measure of the amount of information that can be stored per unit area of memory material. Miniaturization is the most common strategy for increasing storage density. By shrinking the area required to store a bit of information, more bits can be stored in a memory chip of a given size. Miniaturization has been a successful strategy for increasing storage density over the past few decades, but is becoming increasingly more difficult to employ as fundamental size limits of manufacturability are reached.

An alternative approach for increasing storage density is to increase the number of bits stored in a given area of memory. Instead of reducing the area in which information is stored, more bits of information are stored in a particular area of memory. In conventional binary operation, only a single bit of information is stored in each memory location. Higher storage density can be achieved by increasing storage capacity of each memory location. If two bits, for example, can be stored at each memory location, the storage capacity doubles without miniaturizing the memory location. In order to increase the storage capacity of each memory location, it is necessary for the memory material to be operable over more than the two states used in binary (single bit) operation. Two-bit operation, for example, requires a material that is operable over four distinguishable memory states.

Phase-change memory materials have the potential to provide multiple bit operation because of the wide resistance range that separates the set and reset states. In a typical phase-change memory device, the resistance of the set state is on the order of ˜1-10 kΩ, while the resistance of the reset state is on the order of ˜100-1000 kΩ. Since the structural states of a phase-change material are essentially continuously variable over the range of proportions of crystalline and amorphous phase volume fractions extending from the set state to the reset state, multiple bit memory operation at memory states having resistances intermediate between the set resistance and reset resistance is possible.

Although phase-change memory offers the potential for multiple bit operation, progress toward achieving a practical multilevel phase-change memory has been limited. One of the practical complications associated with multilevel phase-change operation is achieving adequate resolution of the different memory states with respect to a programming variable. Another practical complication is a need to achieve reproducible programming to targeted memory states. Reproducibility poses a particular challenge in the face of the normal variations in the programming conditions that accompany memory operation.

As phase-change memory is currently envisioned, different memory states are programmed by varying the applied current. In order to achieve multilevel operation, it is desirable for the resistance of programmed memory states to be an appropriately sensitive function of programming current. If the programmed resistance is relatively insensitive to programming current, poor resolution of the programmed resistance occurs and the range of resistances available for memory states is compressed. If the programmed resistance is too sensitive to programming current, a large change in resistance occurs over a narrow range of current. In this situation, poor resolution of the programming current results as small fluctuations in programming current lead to large changes in resistance and it becomes difficult to unambiguously program memory states having intermediate resistance values.

By focusing on binary operation, the prior art has not paid adequate attention to the need to properly control the sensitivity of programmed resistance with programming conditions to achieve multilevel operation. In order to advance the commercial potential of phase-change memory, it is necessary to develop phase-change materials, device structures or methods of operating phase-change memory devices that provide adequate control over the sensitivity of programmed resistance to programming conditions to enable multilevel operation.

### SUMMARY OF THE INVENTION

This invention provides a device and method of programming to achieve multilevel operation of a variable resistance memory material. The device includes a variable resistance memory material in electrically communication with two or more electrodes, where the device includes an electrode configured to enable controlled dissipation of electrical current or Joule heat in directions lateral to the principle direction of current flow. Controlled lateral dissipation of electrical or thermal energy enables a controlled transformation of the variable resistance material from one structural state to another and provides control over the sensitivity of programmed resistance to programming conditions so that multiple memory states that are well-resolved with respect to both programmed resistance and programming variables can be reliably programmed.

In one embodiment, the variable resistance material is a phase-change material that transforms between a crystalline phase, an amorphous phase, and mixed crystalline-amorphous phases where the resistance of the phase-change material depends on the relative proportions and spatial arrangement of crystalline and amorphous phase regions. In this embodiment, the device provides enough lateral current flow or lateral thermal dissipation to permit precise control over the spatial temperature profile within the phase-change material or at the interface of the phase-change material with an electrode. Through precise control of the temperature profile, especially with respect to the crystallization and/or melting temperature of the phase-change material, the sensitivity of the programmed resistance to programming conditions can be controlled well enough to enable reproducible multilevel operation.

In embodiment, control over lateral transport of electrical or thermal energy in the device is achieved by tailoring the resistivity of one or more electrical contacts. In one embodiment, the resistivity of an electrical contact is between 1 and 100 mΩ-cm. In another embodiment, the resistivity of an electrical contact is between 1 and 20 mΩ-cm. In still another embodiment, the resistivity of an electrical contact is between 2 and 10 mΩ-cm. In a further embodiment, the resistivity of an electrical contact is between 3 and 7 mΩ-cm.

The invention further includes a method of programming a phase-change device to control the sensitivity of programmed resistance to programming conditions. The method includes controlling the resistivity of the programmed state by varying the duration of the electrical pulses used to program the device. In one embodiment, programming to different resistance states occurs by fixing the amplitude of the programming pulse and varying its duration. Variations in pulse duration permit much finer control over the crystalline-amorphous structural transformation than variations in pulse amplitude and enable reproducible transformations to structural states separated by smaller increments in crystalline or amorphous phase volume fraction. As a result, the number of practical programming states is increased and multilevel cell performance is achieved.

### BRIEF DESCRIPTION OF THE DRAWINGS

FIG. 1 is an illustrative Resistance vs. Energy/Current plot for a phase-change material.

FIG. 2 depicts an assignment of resistance values to memory states of a multilevel memory device.

FIG. 3 illustrates the sensitivity of the resistance of a phase-change material to programming variable in a typical prior art device.

FIG. 4 illustrates a resistance response curve having a sensitivity to programming parameter that better facilitates multilevel operation.

FIG. 5 depicts a phase-change memory device having an electrode with low lateral resistivity.

FIG. 6 shows the variation of the resistance of the device depicted in FIG. 5 as a function of pulse width at different reset amplitudes.

FIG. 7 depicts a phase-change memory device having an electrode with high lateral resistivity.

FIG. 8 shows the variation of the resistance of the device depicted in FIG. 7 as a function of pulse width at different reset amplitudes.

FIG. 9 depicts a phase-change memory device having an electrode with intermediate lateral resistivity.

FIG. 10 shows the variation of the resistance of the device depicted in FIG. 9 as a function of pulse width at different reset amplitudes.

### DETAILED DESCRIPTION OF THE ILLUSTRATED EMBODIMENTS

Although this invention will be described in terms of certain preferred embodiments, other embodiments that are apparent to those of ordinary skill in the art, including embodiments that do not provide all of the benefits and features set forth herein, are also within the scope of this invention. Accordingly, the scope of the invention is defined only by reference to the appended claims.

This invention is directed at a device and method for achieving multilevel programming capability in a variable resistance memory cell. The invention seeks to enlarge the number of reproducibly accessible memory states by providing finer control over the mechanism underlying transformations between memory states. In one embodiment, the variable resistance material is a phase-change material and the underlying mechanism of operation is a structural transformation between amorphous and crystalline phases. In this embodiment, the instant invention provides finer control over the volume fractions of amorphous and crystalline phase regions in the phase-change material. Since the resistance of the programmed state is a sensitive function of crystalline vs. amorphous phase volume fraction, the instant invention provides finer control over the programmed resistance and enables a greater number of memory states within a given resistance interval as a result.

In order to appreciate the benefits of the instant invention, it is helpful to review the basic operational characteristics of phase-change memory devices and to discuss issues that complicate the extension of phase-change memory to multilevel performance. The following discussion focuses on chalcogenide materials as illustrative phase-change materials. The basic principles apply equally to other forms of phase-change or state-change materials, such as pnictides or other classes of materials transformable between two or more states distinguishable on the basis of structure, a physical property or a chemical property.

Chalcogenide phase-change materials may also be referred to herein as chalcogenide memory materials or phase-change memory materials. Chalcogenide memory materials have been discussed in U.S. Pat. Nos. 5,166,758; 5,296,716; 5,534,711; 5,536,947; 5,596,522; and 6,087,674; the disclosures of which are hereby incorporated by reference.

An important feature of the operation of chalcogenide-based phase-change memory devices and arrays is the ability of the chalcogenide memory material to undergo a phase transformation between or among two or more structural states. The chalcogenide memory materials have structural states that include a crystalline state, one or more partially-crystalline states and an amorphous state. The crystalline state may be a single crystalline state or a polycrystalline state. The amorphous state may be a glassy state, vitreous state, or other state lacking long range structural order. A partially-crystalline state refers to a structural state in which a volume of chalcogenide or phase-change material includes an amorphous portion and a crystalline portion. Generally, a plurality of partially-crystalline states exists for the chalcogenide or phase-change material, where different partially-crystalline states may be distinguished on the basis of the relative proportion of amorphous and crystalline regions. Fractional crystallinity is one way to characterize the structural states of a chalcogenide phase-change material. The fractional crystallinity of the crystalline state is 100%, the fractional crystallinity of the amorphous state is 0%, and the fractional crystallinities of the partially-crystalline states may vary continuously between 0% (the amorphous limit) and 100% (the crystalline limit). Phase-change chalcogenide materials are thus able to transform among a plurality of structural states that vary inclusively between fractional crystallinities of 0% and 100%.

Transformations among the structural states are induced by providing energy to the chalcogenide memory material. Energy in various forms can induce structural transformations of the crystalline and amorphous portions to alter the fractional crystallinity of a chalcogenide memory material. Suitable forms of energy include one or more of electrical energy, thermal energy, optical energy or other forms of energy (e.g. particle-beam energy) that induce electrical, thermal or optical effects in a chalcogenide memory material. Continuous and reversible variability of the fractional crystallinity is achievable by controlling the energy environment of a chalcogenide memory material. A crystalline state can be transformed to a partially-crystalline or an amorphous state, a partially-crystalline state can be transformed to a crystalline, amorphous or different partially-crystalline state, and an amorphous state can be transformed to a partially-crystalline or crystalline state through proper control of the energy environment of a chalcogenide memory material. Some considerations associated with the use of thermal, electrical and optical energy to induce structural transformations are presented in the following discussion.

The use of thermal energy to induce structural transformations exploits the thermodynamics and kinetics associated with the crystalline to amorphous or amorphous to crystalline phase transitions. An amorphous phase may be formed, for example, from a partially-crystalline or crystalline state by heating a chalcogenide material above its melting temperature and cooling at a rate sufficient to inhibit the formation of crystalline phases. A crystalline phase may be formed from an amorphous or partially-crystalline state, for example, by heating a chalcogenide material above the crystallization temperature for a sufficient period of time to effect nucleation and/or growth of crystalline domains. The crystallization temperature is below the melting temperature and corresponds to the minimum temperature at which crystallization may occur. The driving force for crystallization is typically thermodynamic in that the free energy of a crystalline or partially-crystalline state in many chalcogenide memory materials is lower than the free energy of an amorphous state so that the overall energy of a chalcogenide memory material decreases as the fractional crystallinity increases. Formation (nucleation and growth) of a crystalline state or crystalline domains within a partially-crystalline or amorphous state is kinetically enabled above the crystallization temperature, so that heating (even below the melting point) promotes crystallization by providing energy that facilitates the rearrangements of atoms needed to form a crystalline phase or domain. The fractional crystallinity of a partially-crystalline state can be controlled by controlling the temperature or time of heating or by controlling the temperature or rate of cooling of an amorphous or partially-crystalline state. Through proper control of the peak temperature, time of heating and rate of cooling, structural states over the full range of fractional crystallinity can be achieved for the chalcogenide phase-change materials.

The use of electrical energy to induce structural transformations relies on the application of electrical (current or voltage) pulses to a chalcogenide memory material. The mechanism of electrically-induced structural transformations is based on the Joule heating created by resistance of the material to current flow. Joule heating corresponds to a conversion of electrical energy to thermal energy and leads to an increase in the temperature of the chalcogenide material. By controlling the current density, the temperature can be increased to above the crystallization temperature, between the crystallization temperature and melting temperature, or above the melting temperature.

The crystalline phase portions of a chalcogenide memory material are sufficiently conductive to permit current densities that provide adequate Joule heating. The amorphous phase portions, however, are much less conductive and ordinarily would not support current densities sufficient to heat the material to the crystallization temperature or melting temperature. It turns out, however, that the amorphous phase of chalcogenide memory materials can be electrically switched to a highly conductive “dynamic” state upon application of a voltage greater than the threshold voltage. In the dynamic state, an amorphous phase region of a chalcogenide phase-change material can support a current density that is high enough to heat the material to or above the crystallization or melting temperature through Joule heating. As a result, nucleation and/or growth of a crystalline phase can be induced in an amorphous phase region. (For more information on electrical switching in chalcogenide materials see U.S. Pat. No. 6,967,344 entitled “Multi-Terminal Chalcogenide Switching Devices”.) By controlling the magnitude and/or duration of electrical pulses applied to a chalcogenide phase-change material, it is possible to continuously vary the fractional crystallinity through controlled interconversion of the crystalline and amorphous phases.

The effect of electrical stimulation on a chalcogenide memory material is generally depicted in terms of the R-I (resistance-current) relationship of the material. The R-I relationship shows the variation of the programmed electrical resistance of a chalcogenide memory material as a function of the amount of electrical energy provided or as a function of the magnitude of the current or voltage pulse applied to a chalcogenide memory material. The R-I response is a convenient representation of the effect of crystalline-amorphous structural transformations on electrical resistance. A brief discussion of the R-I characteristics of chalcogenide memory materials follows.

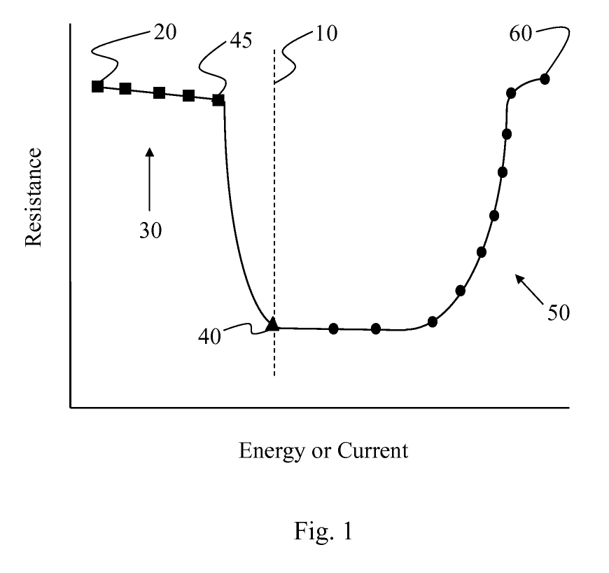

A representative depiction of the electrical resistance (Resistance) of a chalcogenide memory material as a function of electrical energy or current pulse magnitude (Energy/Current) is presented in the resistance plot shown in FIG. 1. The resistance plot includes two characteristic response regimes of a chalcogenide memory material to electrical energy. The regimes are approximately demarcated with the vertical dashed line 10 shown in FIG. 1. The regime to the left of the line 10 may be referred to as the accumulating regime of the memory material. The accumulation regime is distinguished by a nearly constant or gradually varying electrical resistance with increasing electrical energy that culminates in an abrupt decrease in resistance at a critical energy (which may be referred to herein as the set energy). The accumulation regime thus extends, in the direction of increasing energy, from the leftmost point 20 of the resistance plot, through a plateau region (generally depicted by 30) corresponding to the range of points over which the resistance variation is small or gradual to the set point or state 40 that follows an abrupt decrease in electrical resistance. Plateau 30 may be horizontal or sloping.

The left side of the resistance plot is referred to as the accumulating regime because the structural state of the chalcogenide material cumulatively evolves as energy is applied. More specifically, the fractional crystallinity of the structural state increases with the total applied energy so that the material “accumulates” crystalline phase content in this regime. The leftmost point 20 corresponds to the structural state in the accumulating regime having the lowest fractional crystallinity and may be referred to as the reset state. This state may be fully amorphous or may be primarily amorphous with some degree of crystalline content. As energy is added, the chalcogenide material progresses among a plurality of partially-crystalline states with increasing fractional crystallinity along plateau 30 as crystalline phase regions accumulate in the material. Selected accumulation states (structural states in the accumulation region) are marked with squares in FIG. 1.

Upon accumulation of a sufficient amount of crystalline phase content, the fractional crystallinity of the chalcogenide memory material increases sufficiently to effect a setting transformation. The setting transformation is characterized by a dramatic decrease in electrical resistance and culminates in stabilization of set state 40. The structural states in the accumulation regime may be referred to as accumulation states of the chalcogenide memory material. Structural transformations in the accumulating regime are unidirectional in that they progress in the direction of increasing applied energy within plateau region 30 and are reversible only by first driving the chalcogenide material through the set point 40 and the reset point 60, resetting the device. Once the reset state is obtained, lower amplitude current pulses can be applied and the accumulation response of the chalcogenide material can be restored.

The addition of energy to a chalcogenide material in the accumulating regime is believed to lead to an increase in fractional crystallinity through the formation of new crystalline domains, growth of existing crystalline domains or a combination thereof. It is believed that the electrical resistance varies only gradually along plateau 30 despite the increase in fractional crystallinity because the crystalline domains form or grow in relative isolation of each other so as to prevent the formation of a contiguous crystalline network that spans the chalcogenide material between the two electrodes of the memory device. This type of crystallization may be referred to herein as sub-percolation crystallization.

The setting transformation coincides with a percolation event in which a contiguous, interconnected crystalline network forms within the chalcogenide material, where the network bridges the space between the two electrodes of the device. Such a network may form, for example, when crystalline domains increase sufficiently in size to impinge upon neighboring domains. Since the crystalline phase of chalcogenide materials is more conductive than the amorphous phase, the percolation event corresponds to the formation of a contiguous conductive pathway through the chalcogenide material. As a result, the percolation event is marked by a dramatic decrease in the resistance of the chalcogenide material, where the resistance of the material following the percolation event depends on the effective area of the percolation path. The leftmost point 20 of the accumulation regime may be an amorphous state or a partially-crystalline state lacking a contiguous crystalline network. Sub-percolation crystallization commences with an initial amorphous or partially-crystalline state and progresses through a plurality of partially-crystalline states having increasingly higher fractional crystallinities until the percolation threshold is reached and the setting transformation occurs.

The regime to the right of the line 10 of FIG. 1 may be referred to as the direct overwrite regime. The direct overwrite regime extends from set state 40 through a plurality of intermediate states (generally depicted by 50) to a reset point or state 60. The various points in the direct overwrite regime may be referred to as direct overwrite states of the chalcogenide memory material. Selected direct overwrite states are marked with circles in FIG. 1. Structural transformations in the direct overwrite regime may be induced by applying an electric current or voltage pulse to a chalcogenide material. In FIG. 1, an electric current pulse is indicated. In the direct overwrite regime, the resistance of the chalcogenide memory material varies with the magnitude of the applied electric pulse. The resistance of a particular direct overwrite state is characteristic of the structural state of the chalcogenide memory material, and the structural state is dictated by the magnitude of the applied current pulse. The fractional crystallinity of the chalcogenide memory material decreases as the magnitude of the current pulse increases. The fractional crystallinity is highest for direct overwrite states at or near set point 40 and progressively decreases as reset state 60 is approached. The chalcogenide memory material transforms from a structural state possessing a contiguous crystalline network at set state 40 to a structural state that is amorphous or substantially amorphous or partially-crystalline without a contiguous crystalline network at reset state 60. The application of current pulses having increasing magnitude has the effect of converting portions of the crystalline network into an amorphous phase and ultimately leads to a disruption or interruption of contiguous high-conductivity crystalline pathways in the chalcogenide memory material. As a result, the resistance of the chalcogenide memory material increases with increasing applied current in the direct overwrite region.

In contrast to the accumulating region, structural transformations in the direct overwrite region are reversible and bi-directional. As indicated hereinabove, each state in the direct overwrite region may be identified by its resistance and an associated current pulse magnitude, where application of the associated current pulse magnitude induces changes in fractional crystallinity that produce the particular resistance state. Application of a subsequent current pulse may increase or decrease the fractional crystallinity of an existing resistance state of the chalcogenide memory material. If the subsequent current pulse has a higher magnitude than the pulse used to establish the existing state, the fractional crystallinity of the chalcogenide memory material decreases and the structural state is transformed from the existing state in the direction of the reset state along the direct overwrite resistance curve. Similarly, if the subsequent current pulse has a lower magnitude than the pulse used to establish the existing state, the fractional crystallinity of the chalcogenide memory material increases and the structural state is transformed from the existing state in the direction of the set state along the direct overwrite resistance curve.

The direct overwrite states of the chalcogenide memory material may be used to define memory states of a memory device. Most commonly, the memory devices are binary memory devices that utilize two of the direct overwrite states as memory states, where a distinct data value (e.g. “0” or “1”) is associated with each state. Each binary memory state corresponds to a distinct structural state of the chalcogenide material. Readout or identification of the state can be accomplished by measuring the resistance of the material (or device) since each structural state is characterized by a distinct resistance value. The operation of transforming a chalcogenide memory material to the structural state associated with a particular memory state may be referred to herein as programming the chalcogenide memory material, writing to the chalcogenide memory material or storing information in the chalcogenide memory material. The resistance of the memory state established by programming the chalcogenide memory material may also be referred to herein as the programmed resistivity of the material or programmed resistance of the device.

To facilitate readout and minimize reading errors, it is desirable to select the memory states of a binary memory device so that the contrast in resistance of the two states is large. Typically the set state (or a state near the set state) and the reset state (or a state near the reset state) are selected as memory states in a binary memory application. The resistance contrast depends on details such as the chemical composition of the chalcogenide, the thickness of the chalcogenide material in the device and the geometry of the device. For a layer of phase-change material having the composition Ge₂₂Sb₂₂Te₅₆, a thickness of ˜600 Å, and pore diameter of below ˜0.1 μm in a typical two-terminal device geometry, for example, the resistance of the reset state is ˜100-1000 kΩ and the resistance of the set state is under ˜10 kΩ. Phase-change devices in general show resistances in the range of ˜100 kΩ to ˜1000 kΩ in the reset state and resistance of ˜0.5 kΩ to ˜50 kΩ in the set state. In the preferred phase-change devices, the resistance of the reset state is at least a factor of two, and more typically an order of magnitude or more, greater than the resistance of the set state.

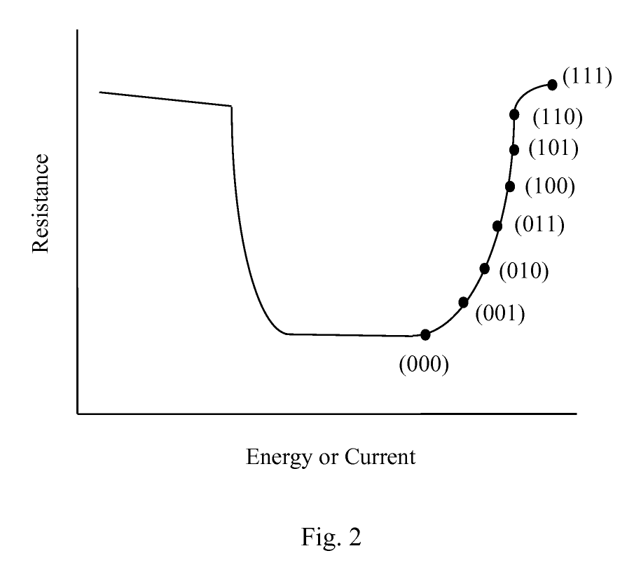

This invention seeks to extend the applicability of chalcogenide memory materials beyond binary (single bit) memory applications to multilevel (non-binary or multiple bit) memory applications. The storage density of a multilevel chalcogenide memory device improves as the number of memory states increases. As described hereinabove, the direct overwrite region of the resistance plot of a chalcogenide or phase-change material includes a plurality of states that differ in resistance over a resistance interval extending from the set state to the reset state. Multilevel memory operation can be achieved by selecting three or more states from among the direct overwrite states and associating a unique data value with each. Each of the three or more states corresponds to a distinct structural state of the chalcogenide and is characterized by a distinct resistance value. Two bit operation can be achieved by selecting four direct overwrite states to serve as memory states, three bit operation can be achieved by selecting eight direct overwrite states to serve as memory states, etc. FIG. 2 shows an illustrative selection of eight direct overwrite states for use as memory states in a three-bit memory device. One assignment of data values to the different states is also shown, where the (000) state corresponds to the set state, the (111) state corresponds to the reset state, and a series of intermediate resistance states is included.

To improve the storage density in a multilevel memory device, it is desirable to operate the memory material over as many states as possible. The number of memory states is controlled by the resistance interval between the set state and reset state, the resolution limit of the resistance measurement performed during the read operation, the stability of the resistance values, and the sensitivity of programmed resistance to programming conditions. A large resistance difference between the set and reset states provides a wide dynamic range of resistance over which operation of the memory device can occur. The resolution limit of the read resistance measurement imposes a practical limit on the spacing of resistance values associated with the different memory states. The resolution limit depends on read noise and read circuit limitations. The resistance differential between adjacent memory states must be greater than the resolution of the read resistance measurement. Stable resistance values are needed to insure that programmed resistance values do not vary (drift) in time.

This invention is concerned with the sensitivity of programmed resistance to programming conditions. This sensitivity is an important consideration for multilevel operation because it determines the resolution required in the programming conditions. As indicated hereinabove, multilevel programming requires an adequate difference in resistance between consecutive memory states so that the individual states can be unambiguously resolved in a read operation. Adequate resistance contrast between consecutive memory states is not, however, sufficient by itself to enable practical multiple bit memory operation. It is further necessary that the programming conditions required to achieve the different resistance states are adequately resolved. As used herein, programming conditions refer to parameters such as the amplitude, duration, or shape of the energetic waveforms used to program the memory material. For electrical programming, programming conditions corresponds to parameters such as current pulse amplitude, current pulse duration, voltage pulse amplitude, voltage pulse duration, rise time (or shape of leading edge) of a voltage or current pulse, and fall time (or shape of trailing edge) of a voltage or current pulse.

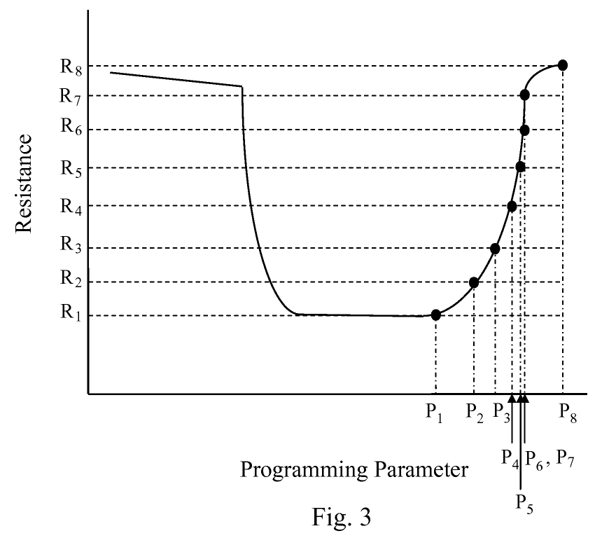

The significance of the sensitivity of the resistance of a chalcogenide memory material to programming conditions is illustrated in FIG. 3. FIG. 3 depicts the resistance of a three-bit memory device as a function of a programming parameter, where the sensitivity of resistance to the programming parameter is similar to that shown in FIG. 2. The eight memory states in FIG. 3 are depicted as filled circles and are labeled according to the resistance of the memory state and the value of the programming parameter required to establish the memory state. (For example, R₁ denotes the resistance of memory state 1 and P₁ denotes the value of the programming parameter required to establish memory state 1.)

Additional lines are included in FIG. 3 to illustrate the sensitivity of programmed resistance to programming conditions. The dashed (- - - -) lines mark the resistance of each memory state and the dot-dash (- . - . - .) lines mark the value of the programming parameter of each memory state. The resistance plot of FIG. 3 shows good resolution of the resistance of the eight memory states. The resistance of each memory state is well-resolved from the resistance of adjacent memory states. The resolution in programming parameter, however, is poor for several of the memory states. In particular, programming parameters P₄, P₅, P₆, and P₇ for memory states 4, 5, 6, and 7 are bunched and difficult to resolve.

The poor resolution in programming parameter is a consequence of the high sensitivity of resistance to programming parameter. The high sensitivity is a reflection of the steep slope of the resistance plot in the region of intermediate memory states between state 1 (which may have the resistance of the set state) and state 8 (which may have the resistance of the fully reset state). Because of the high sensitivity, a small fluctuation or deviation in the value of the programming parameter produces a significant variation in resistance. As a result, high sensitivity of resistance to programming parameter makes it difficult to stabilize intermediate resistance states with any degree of reliability.

In FIG. 3, for example, memory states 6 and 7 are well resolved in resistance, but have essentially the same value of the programming parameter because of the nearly vertical shape of the resistance plot in the vicinity of states 6 and 7. As a second example, one wishing to program memory state 5 in FIG. 3 needs to apply programming parameter P₅ to the memory device. A small variation in the intended programming parameter P₅, however, may lead to an actual value of the programming parameter that is closer to P₄ or P₆ and thus may result in a device having a resistance closer to R₄ or R₆ when the device is read. As a result, an error occurs on reading.

The sensitivity of the programmed resistance of a memory state of a phase-change device to programming parameter is ultimately determined by the programmer's ability to control the characteristics of the crystalline-amorphous phase transition. Since the resistivity of the crystalline phase is significantly lower than the resistivity of the amorphous phase, the relative proportions of the crystalline and amorphous phase regions in the phase-change material of the memory device influence the resistance of a programmed state. In addition to the relative amounts, the spatial arrangement of crystalline and amorphous phase regions influences the programmed resistance. Low programmed resistance is promoted by an arrangement of crystalline phase regions that extends contiguously between the two contacts of the device. For a given crystalline phase volume fraction within the phase-change material, a contiguous arrangement of crystalline phase regions leads to a lower resistance than a non-contiguous arrangement.

If the crystalline phase regions are arranged non-contiguously, the space between crystalline phase regions is occupied by phase-change material in the amorphous phase. As a result, current through the device must pass at least partially through high resistance amorphous phase regions that are in series with the non-contiguous crystalline phase regions and the overall resistance of the programmed state increases. In a non-contiguous arrangement of crystalline and amorphous regions having a particular crystalline volume fraction, the spatial arrangement of crystalline regions and amorphous regions also influences the resistance. At a given crystalline volume fraction, the arrangement of crystalline domains that minimizes the size of the gaps between the amorphous phase regions promotes establishment of a low resistance state. As the presence of amorphous phase regions in the pathway for current flow between device electrodes increases, the resistance of the programmed state increases (and vice versa).

The number and cross-section of contiguous crystalline pathways for current flow through the phase-change material also influence the resistance of a programmed state. An arrangement of crystalline phase regions that provides for multiple contiguous crystalline pathways that occupy a substantial volume of the phase-change material best promotes a low resistance programmed state. In one model, the reset state of a phase-change material may be viewed as a substantially amorphous phase that lacks contiguous crystalline pathways. Crystalline phase regions may be present in the reset state, but they occupy a low volume fraction and are either spatially isolated and disconnected, or are connected with very low cross-section pathways (for example, for a cross-sectional area of 4E-14 cm², the resistance for a 600 Å path length through a pathway with a resistivity of 0.02 Ohm cm is ˜3MΩ, a resistance comparable to or greater than the resistance through a larger cross-section amorphous pathway). As the volume fraction of crystalline phase regions increases and the crystalline phase regions become more interconnected, the resistance of the programmed state decreases. The minimum resistance coincides with the set state, which may be viewed as a state having a high crystalline phase volume fraction and higher cross-section, contiguous crystalline pathways. Programmed states having resistances between the set resistance and reset resistance have intermediate degrees of crystalline phase volume fraction and connectivity of crystalline phase domains.

In order to achieve reliable multilevel memory operation, it is necessary to be able to precisely and reproducibly control the crystalline phase volume fraction as well as the physical arrangement, connectivity, rate of formation, and spatial dimensions of crystalline phase regions within the phase-change material. Achieving the requisite control is difficult because the resistance of the programmed state is a complicated function of the characteristics of the crystalline phase regions. Depending on where crystalline phase regions are formed upon application of the programming current, for example, the change in resistance induced by programming may be large or small. Control over the characteristics of the crystalline phase regions, in turn, is a complicated function of the programming parameter.

As indicated hereinabove, control over the relative proportions of the crystalline and amorphous phase regions requires control over the temperature of the phase-change material relative to the crystallization and melting temperatures. Crystallization requires establishing a temperature between the crystallization and melting temperatures and maintaining the temperature for a period of time sufficient to permit formation of a crystalline phase. The material may be heated directly to a temperature between the crystallization temperature and melting temperature. Alternatively, the material may be heated to a temperature above the melting temperature followed by a slow quench that permits the material to reside at a temperature between the crystallization and melting temperatures for a sufficiently long period of time as the material cools down. Formation of amorphous phase regions requires heating the phase-change material to a temperature above the melting temperature followed by a quench that is sufficiently fast to prevent crystallization.

Control over the spatial arrangement of crystalline and amorphous phase regions requires control over the distribution of thermal energy in the phase-change material. The distribution of thermal energy establishes the temperature profile of the phase-change material and determines the spatial positions within the material that are heated to below the crystallization temperature, to a temperature between the crystallization temperature and the melting temperature, and to above the melting temperature. The time variation of the distribution of thermal energy governs heating and cooling rates.

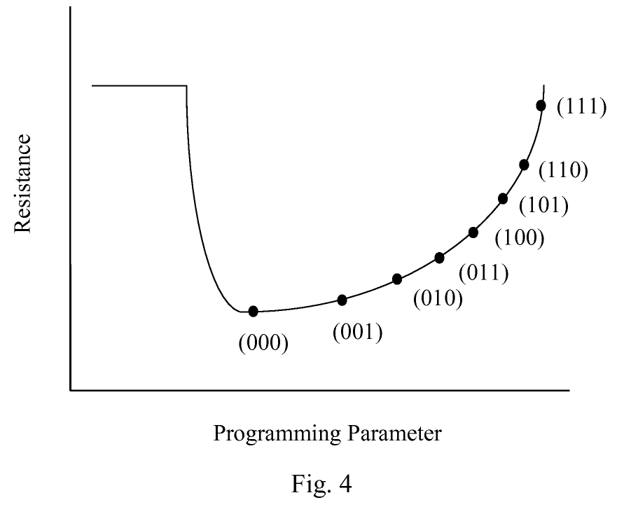

The degree of control over the distribution of thermal energy within a phase-change material has been inadequate in the prior art to achieve the sensitivity in the variation of resistance as a function of programming parameter desired for a multilevel cell. FIG. 4 illustrates a phase-change response curve that provides a more favorable multilevel behavior. In contrast to FIG. 3, the resistance of the phase-change device varies only gradually as the programming parameter increases. The flatter response curve extends the range in programming parameter over which the resistance changes and permits greater spacing of memory states with respect to programming parameter. As a result, the memory device is more tolerant of fluctuations in programming parameter and it becomes easier to unambiguously define multiple memory states for the device. This remains the case even though some compression in resistance may occur in the low resistance regime of the response curve because of the high degree of resolution available for resistance measurements.

Achievement of a flattened response curve requires fine control over the amount and spatial distribution of thermal energy in the phase-change material, which in turn requires fine control over the conversion of electrical energy into thermal energy through Joule heating. In the prior art, it has been difficult to control the flow of electric current to deliver the spatial distribution of thermal energy needed to stabilize the spatial arrangement and volume fraction of amorphous and crystalline phases required to achieve each of several intermediate resistance states with sufficient precision. In the prior art, the tendency has been for the relative proportions of crystalline and amorphous phase regions to change abruptly to produce a large change in resistance over a narrow range of programming parameter. The instant inventors believe that the abrupt change in volume fraction observed in the prior art is due to an inability to properly control the production and dissipation of thermal energy produced by the electric current in Joule heating.

The instant invention provides a method and device structure that enables finer control over the distribution of thermal energy produced by the electric current used to program a phase-change material. More specifically, the instant inventors have discovered that the relative proportions and spatial arrangement of crystalline and amorphous phase regions in a phase-change material can be more precisely established by controlling the dissipation of thermal energy produced by Joule heating in a device electrode in directions lateral to the direction of current flow. By regulating the duration of the electrical pulse used to program the phase-change material and fixing the resistivity of a device electrode in a particular range, the instant invention permits control over the lateral dissipation of thermal energy and the temperature profile within the phase-change material. As a result, the volume fraction and spatial configuration of amorphous and crystalline phase regions can be controlled in a more continuous and less abrupt manner than is possible in the prior art. The net result is a resistance response curve for the phase-change device that has better resolved resistance states and programming levels and thus better suitability for multilevel operation than prior art devices.

One aspect of the instant invention is a programming method utilizing electrical current pulses whereby the resistance of the programmed state is controlled by the pulse duration. (Pulse duration may also be referred to herein as pulse width.) The instant inventors have discovered that pulse width is an effective programming parameter for achieving multiple well-resolved resistance states when the resistivity of a device electrode is in a preferred range. While not wishing to be bound by theory, the instant inventors believe that the preferred resistivity range corresponds to a range in which lateral dissipation of the thermal energy produced by the programming current is tailored to promote a softer resistance response of the device. Illustration and explanation of the principles that may underlie the benefits provided by the instant invention are described in the following examples.

### EXAMPLE I

In this example, the effect of pulse width on the programmed resistance of a phase-change device having a lower electrode with low resistivity is described.

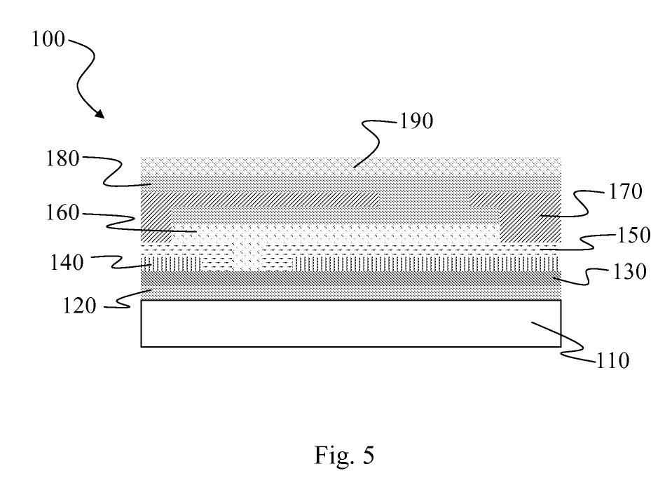

FIG. 5 depicts a typical phase-change memory device 100 that includes base wafer 110, dielectric buffer 120, lower electrode 130, conductive line 140, dielectric 150, phase-change material 160, dielectric 170, upper electrode 180, and conductive line 190. Conductive lines 140 and 190 receive and deliver electrical signals to surrounding circuitry and may, for example, be a word line and a bit line of a memory device in an array. In device 100, current is delivered from an external device through conductive line 140 and lower electrode 130 to phase-change material 160 and upper electrode 180 and conductive line 190. Phase-change material 160 has the composition Ge₂Sb₂Te₅. The direction of current flow in device 100 is generally vertical between the portion of lower electrode 130 in contact with phase-change material 160 and the portion of upper electrode 180 disposed immediately above such portion of lower electrode 130.

Lower electrode 130 in this example has a resistivity below 1 mΩ-cm. The low resistivity of lower electrode 130 leads to efficient flow of current in all directions through lower electrode 130, including in the generally vertical direction of current flow toward upper electrode 180 and in directions lateral thereto. Since thermal resistivity generally tracks electrical resistivity, lower electrode 130 also exhibits efficient lateral dissipation of thermal energy. Lower electrode 130 in this example is an unannealed form of TiAlN. Materials such as TiW and unannealed forms of other metal nitrides (e.g. TiN, TiSiN) are also illustrative of lower electrode materials that distribute thermal energy produced by Joule heating in accordance with this example.

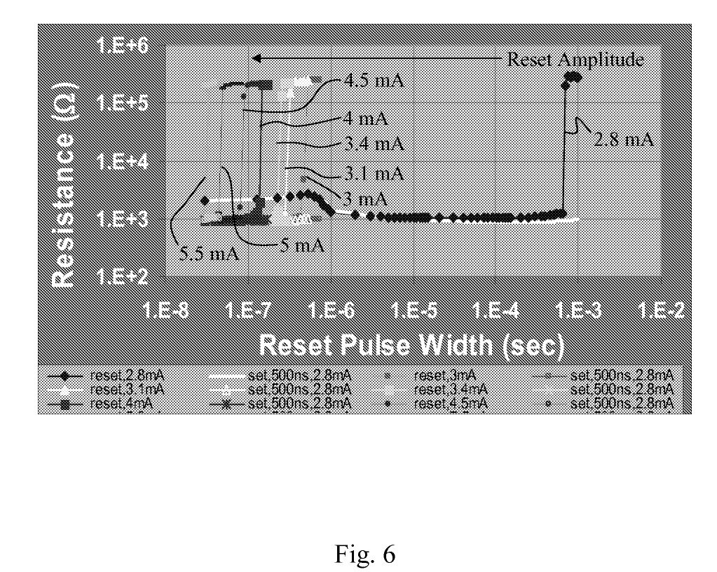

FIG. 6 shows the effect of pulse width on the resistance of the device depicted in FIG. 5. In the experiment, the device was initialized with a set pulse having an amplitude of 2.8 mA and a pulse width of 500 ns. The initializing set pulse placed the device in a set state having a resistance of ˜1 kΩ. The device was then cycled with an alternating series of reset pulses and set pulses. A common set pulse having the amplitude and duration of the initializing pulse was applied for all trials. A series of trials utilizing reset pulses of fixed amplitude and variable duration were performed. For each trial at a particular fixed amplitude, a reset pulse having a particular duration was applied to the device and the device resistance was measured. After the resistance measurement was completed, a set pulse was applied and subsequently another reset pulse at the particular fixed amplitude having a different duration was applied. The resistance was measured and the procedure was repeated for several cycles over a range of pulse durations. For each trial, cycling at fixed pulse amplitude and progressively increasing pulse duration was continued until the device was transformed to its reset state. The procedure was repeated for a series of fixed reset pulse amplitudes between 2.8 mA and 5.5 mA.

The results of the trials are shown in FIG. 6, which displays a series of traces showing the dependence of device resistance on reset pulse width. Each trace is depicted with a common symbol and corresponds to a trial at a particular fixed reset amplitude, where the reset amplitude corresponding to each trace is labeled in the figure and noted in the legend. The direction of increasing reset pulse amplitude is also noted in FIG. 6. For reference purposes, the set resistance of each cycle of each trial at a particular fixed reset pulse amplitude is also shown in FIG. 6.

The general appearance of each trace is similar. For each fixed reset pulse amplitude, the device resistance is at or close to the set resistance at short pulse durations and abruptly increases to a resistance over 100 kΩ at longer pulse durations. When the reset amplitude is fixed at 2.8 mA, for example, the device resistance remains at ˜1 kΩ up to pulse durations well above 100 μs. As the pulse duration approaches 1 ms, however, the device resistance exhibits an abrupt, nearly discontinuous increase in resistance to over 100 kΩ. As the reset pulse amplitude increases, the same general characteristics are observed for the resistance response trace. The notable difference, however, is that the pulse duration at which the abrupt change in device resistance occurs decreases as the amplitude of the reset pulse increases.

As noted above, an abrupt increase in resistance with programming parameter is undesirable for multilevel memory operation. The results of this example show that when the resistivity of a device electrode is too low, pulse width is an ineffective programming parameter for achieving satisfactory multilevel memory operation. The instant inventors believe that the rapid lateral dissipation of thermal energy created by Joule heating prevents the degree of control needed over the distribution of thermal energy in the phase-change material to reliably establish intermediate resistance states (e.g. states having a resistance between ˜2 kΩ and 100 kΩ in this example). The resolution in pulse width needed to distinguish intermediate resistance states in this example is too fine and too susceptible to ambiguities caused by normal fluctuations in programming conditions to permit reliable multilevel operation. The highly efficient lateral dissipation of thermal energy makes it difficult to achieve the precise control over the relative proportions and spatial arrangement of crystalline and amorphous regions needed to stabilize intermediate resistance states. Instead, the prevailing tendency is for the device to adopt only the states (set state and reset state) at the extremes of the range of resistance potentially available for memory operation.

### EXAMPLE II

In this example, the effect of pulse width on the programmed resistance of a phase-change device having a lower electrode with high lateral resistivity is described.

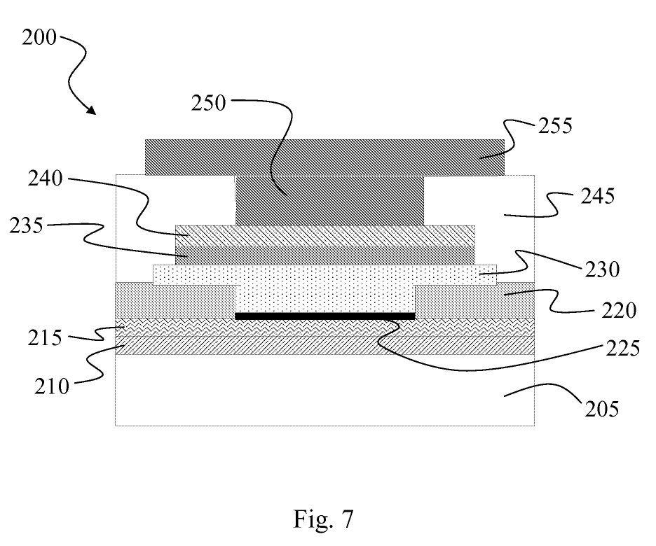

FIG. 7 shows a device structure 200 utilizing a lower electrode having a high resistance to lateral flow of electrical or thermal energy. Device 200 includes base wafer 205, conductive line 210, lower electrode 215, and dielectric 220 having an opening formed therein. Breakdown layer 225 and phase-change material 230 are formed within the opening. Phase-change material 230 is also formed over the opening and on dielectric 220. Device 200 further includes upper electrode 235, metal layers 240 and 250, surrounding dielectric 245, and conductive line 255. Phase-change material 230 has the composition Ge₂Sb₂Te₅ and breakdown layer 225 is a thin insulating layer (having a thickness of ˜10-30 Å).

In device 200, current is delivered from an external device through conductive line 210 to lower electrode 215 and continues through breakdown layer 225 and phase-change material 230 to upper electrode 235 and metal layers 240 and 250. Conductive line 255 receives current passing through the device and delivers it to external circuitry. As is known in the art, the purpose of breakdown layer 225 is to limit the area of contact of phase-change material 230 with lower electrode 215. Upon fabrication, breakdown layer 225 is insulating and prevents current flow between lower electrode 215 and upper electrode 235. During post-fabrication conditioning, application of a sufficient voltage between lower electrode 215 and upper electrode 235 punctures breakdown layer 225 to create a conductive pathway that enables current to flow to phase-change material 230.

Lower electrode 215 is a carbon electrode and has been selected to provide high electrical and thermal resistivity in directions lateral to the generally vertical direction of current flow. Lower electrode 215 is formed by sputter deposition from a carbon target. In its as-deposited state, the carbon is amorphous and highly resistive (resistivity ˜100 mΩ-cm-˜1Ω-cm). The carbon remains resistive in the as-fabricated state of the device. Post-fabrication conditioning of the device (which entails application of voltage pulses between lower electrode 215 and upper electrode 235 to stabilize the performance characteristics of the device) reduces the resistivity of carbon. Application of voltage pulses of a sufficient magnitude across a resistive carbon electrode during conditioning transforms the electrode to a more conductive state. The reduced resistivity, however, does not occur universally throughout the carbon electrode, but rather occurs only over a limited volume of the carbon electrode. Thermal energy produced by current flow through the carbon electrode is the driving force for the conversion of resistive carbon to conductive carbon. As voltage pulses are applied during conditioning, current preferentially flows along low resistance pathways and the resulting thermal energy progressively transforms carbon along and adjacent to the low resistance pathways to a more conductive state. Eventually, a conductive carbon pathway extends across the full vertical depth of the carbon electrode in the direction of current flow and a controlling current pathway is established. The net effect of the conditioning process on a carbon electrode is the establishment of a restricted volume of conductive carbon within a surrounding matrix of highly resistive carbon resistivity above 100 mΩ-cm).

Device 200 of this example has been conditioned so that lower electrode 215 is conductive only over a limited volume having a cross-sectional area that is significantly smaller than the cross-sectional area of phase-change material 230. In one embodiment, the cross-sectional area of the conductive carbon region is comparable to the cross-sectional area of the punctured region of breakdown layer 225 formed during conditioning, estimated to be 500-1000 A in diameter. For purposes of this example, the important aspect of lower electrode 215 is that the highly resistive portion of the electrode that surrounds the conductive portion greatly inhibits lateral dissipation of thermal and electrical energy. Transport of thermal and electrical energy occurs predominantly in the direction of current flow. Device 200 of this example thus differs fundamentally with respect to the efficiency of lateral dissipation of thermal energy from device 100 of Example I.

The resistance of device 200 as a function of pulse width at various fixed reset pulse amplitudes was measured in a manner similar to that described in Example I hereinabove. In the experiment, the device was initialized with a set pulse having an amplitude of 1 mA and a pulse width of 600 ns. The initializing set pulse placed the device in a set state having a resistance of slightly less than 1 kΩ. The device was then cycled with an alternating series of reset pulses and set pulses. A common set pulse having the amplitude and duration of the initializing pulse was applied for all trials. A series of trials utilizing reset pulses of fixed amplitude and variable duration were performed. For each trial at a particular fixed amplitude, a reset pulse having a particular duration was applied to the device and the device resistance was measured. After the resistance measurement was completed, a set pulse was applied and subsequently another reset pulse at the particular fixed amplitude having a different duration was applied. The resistance was measured and the procedure was repeated for several cycles over a range of pulse durations. For each trial, cycling at fixed pulse amplitude and progressively increasing pulse duration was continued up to a maximum pulse duration of several milliseconds. The procedure was repeated for a series of fixed reset pulse amplitudes between 1.15 mA and 2.6 mA.

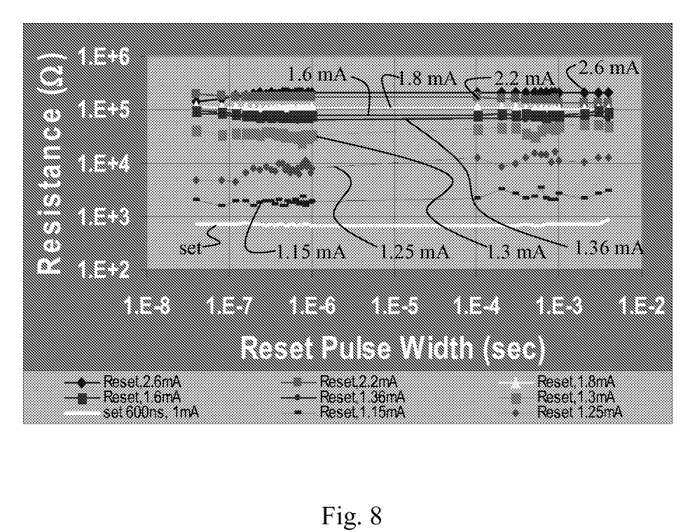

FIG. 8 shows the effect of pulse width on the resistance of the device depicted in FIG. 7. FIG. 8 presents a series of traces, where each trace is depicted with a common symbol and corresponds to a trial at a particular fixed reset amplitude that shows the dependence of device resistance on reset pulse width. The magnitude of the reset pulse amplitude corresponding to each trace is labeled in the figure and noted in the legend. For reference purposes, the set resistance on cycling at fixed reset pulse parameters is also shown in FIG. 8.

The general appearance of each trace is similar. For each reset pulse amplitude, the device resistance is nearly independent of pulse width. At a reset pulse amplitude of 1.15 mA, for example, the resistance of the device remained constant at a few kΩ for pulse durations ranging from ˜50 ns up to several milliseconds. As the reset pulse amplitude increases, the same general characteristics are observed for the resistance response trace. The notable difference, however, is that the device resets to a progressively higher constant resistance as the amplitude of the reset pulse increases. When the reset pulse amplitude is 2.6 mA, the resistance of the device remains nearly constant at a value of slightly above 100 kΩ as the pulse width increases.

The results of this example show that when the device electrode exhibits high resistivity to lateral dissipation of thermal energy, pulse width is an ineffective programming parameter for achieving satisfactory multilevel memory operation. The instant inventors believe that the lateral dissipation of thermal energy created by Joule heating in device 200 is too low to achieve the necessary degree of control over the spatial distribution of thermal energy in the phase-change material through variations in pulse width. The lack of lateral thermal dissipation effectively confines current flow and the thermal energy it creates to the restricted conductive portion of lower electrode 215. Because of the high lateral resistance, the increase in thermal energy produced by increasing the pulse duration cannot be productively harnessed for the purpose of achieving greater control over the spatial temperature profile within phase-change material 230. The high lateral resistivity, for example, precludes the use of the excess thermal energy obtained at long pulse durations to expand the area of contact between lower electrode 215 and phase-change material 230 over which a particular temperature (e.g. relative to the crystallization or melting temperatures of the phase-change material) is maintained. As a result, the ability to control the temperature profile within the phase-change material in directions lateral to the direction of current flow is compromised and pulse width becomes an insufficiently sensitive programming variable for achieving multilevel operation.

### EXAMPLE III

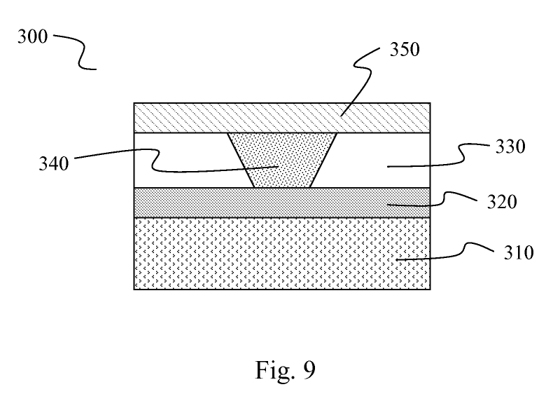

In this example, the effect of programming pulse width on the resistance of a device in accordance with the instant invention is described. The device is shown as device 300 in FIG. 9. Device 300 includes base wafer 310, lower electrode 320, phase-change material 340 positioned within an opening of surrounding dielectric 330, and upper electrode 350. Phase-change material 340 is Ge₂Sb₂Te₅. In device 300, current is delivered from an external device through a conductive line connected to lower electrode 320 and continues through phase-change material 340 to upper electrode 350.

Lower electrode 320 is an intermediate resistivity form of TiAlN obtained by annealing TiAlN at 400° C. The resistivity of the annealed electrode material is ˜3-6 mΩ-cm. Other electrode materials (e.g. TiSiN, TiW, TiN, MoN, nitrogenated carbon) provide a resistivity in a range providing the benefits of the instant invention if annealed to a temperature appropriate for the material. The resistivity of lower electrode 320 is generally isotropic and provides for a lateral resistance to the dissipation of thermal energy that is intermediate between lower electrode 130 of Example 1 and lower electrode 215 of Example 2. The intermediate lateral resistance of lower electrode 320 permits an intermediate degree of lateral dissipation of thermal energy and an intermediate degree of current flow in lateral directions. As described more fully hereinbelow, the intermediate degrees of lateral thermal dissipation and current flow enable a mechanism by which the distribution of thermal energy within the phase-change material can be controlled. Through this mechanism, the instant invention provides sufficient control over the relative proportions and spatial arrangement of crystalline and amorphous regions within the phase-change material.

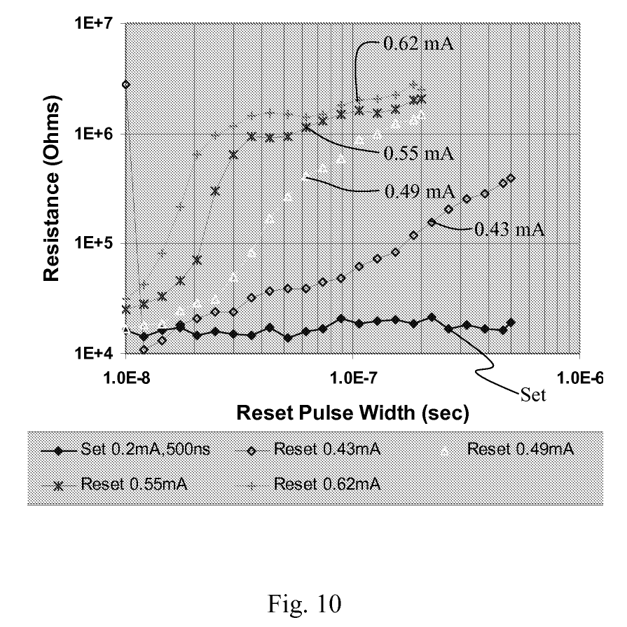

FIG. 10 shows the effect of pulse width on the resistance of the device depicted in FIG. 9. In the experiment, the device was initialized with a set pulse having an amplitude of 0.2 mA and a pulse width of 500 ns. The initializing set pulse placed the device in a set state having a resistance of slightly above 10 kΩ. The device was then cycled with an alternating series of reset pulses and set pulses. A common set pulse having the amplitude and duration of the initializing pulse was applied for all trials. A series of trials utilizing reset pulses of fixed amplitude and variable duration were performed. For each trial at a particular fixed amplitude, a reset pulse having a particular duration was applied to the device and the device resistance was measured. After the resistance measurement was completed, a set pulse was applied and subsequently another reset pulse at the particular fixed amplitude having a different duration was applied. The resistance was measured and the procedure was repeated for several cycles over a range of pulse durations. For each trial, cycling at fixed pulse amplitude and progressively increasing pulse duration was continued until the pulse duration was at least 200 ns. The procedure was repeated for a series of fixed reset pulse amplitudes between 0.43 mA and 0.62 mA.

The results of the trials are shown in FIG. 10, which displays a series of traces showing the dependence of device resistance on reset pulse width. Each trace is depicted with a common symbol and corresponds to a trial at a particular fixed reset amplitude, where the reset amplitude corresponding to each trace is labeled in the figure and noted in the legend. For reference purposes, the set resistance at different pulse widths is also shown in FIG. 10.

The data shown in FIG. 10 indicate that the variation of device resistance with pulse width depends on reset amplitude. When the reset amplitude is 0.43 mA, the device resistance increases gradually with increasing pulse width. The gradual variation in device resistance with pulse width extends the operable range of pulse width associated with the range of resistance states available in the phase-change material. The wider operable range of pulse width provides greater certainty and reproducibility in the programming of intermediate resistance states and thus facilitates multilevel operation. The gradual resistance response curve observed at a reset amplitude of 0.43 mA has the desirable characteristics discussed in connection with FIG. 4 hereinabove. Multiple memory states that are well-resolved in both resistance and pulse width can readily be defined for the resistance response curve observed at 0.43 mA. As a result, reliable multilevel operation with high margins and a high degree of tolerance for typical fluctuations in the programming and read processes can be readily achieved.

As the reset amplitude increases above 0.43 mA in this example, the shape of the resistance response curve of the device evolves toward the steeper response observed in the prior art. The resistance response at a reset amplitude of 0.49 mA maintains characteristics favorable to multilevel operation, but suitability for multilevel operation diminishes at reset amplitudes of 0.55 mA and 0.62 mA as the steepness of the response curve increases. The steeper response curve compresses the operable interval of pulse widths and introduces the difficulties in achieving reliable multilevel operation described hereinabove in connection with FIG. 3.

The controlled, less abrupt increase in device resistance observed in this example at reset amplitudes of 0.43 mA and 0.49 mA is believed to result from more precise control over the distribution of thermal energy in the phase-change material. The intermediate lateral resistivity of lower electrode 320 allows for enough lateral dissipation of thermal energy and/or lateral current flow to enable programming pulse width to influence the distribution of thermal energy in the phase-change material to an extent sufficient to provide a reliable and incremental degree of control over the relative amounts and/or spatial configuration of amorphous and crystalline phase regions in phase-change material 340.

At the higher reset amplitudes of this example, it is believed that the amount of thermal energy produced by Joule heating overwhelms the ability of lower electrode 320 to effectively manage the distribution of thermal energy. As described more fully hereinbelow, the desired degree of control over the structural characteristics of the phase-change material requires a spatial differentiation of temperatures with respect to the crystallization and melting temperatures of the phase-change material over the cross-sectional dimension of the area of contact of the lower electrode with the phase-change material. To achieve fine control over the structural characteristics, it is desirable to have the ability to establish a temperature profile over the cross-section of the phase-change material in which different regions are selectively heated to temperatures below the crystallization temperature, temperatures between the crystallization temperature and melting temperature, and/or temperatures above the melting temperature. Spatial differentiation of the temperature profile with respect to the crystallization and melting temperatures enhances control over the programming process.

At the high reset amplitudes of this example, it is possible that the current density entering phase-change material 340 is sufficiently high over a sufficiently extended lateral area relative to the area of contact of phase-change material 340 with lower electrode 320 to preclude differential control over the temperature profile of phase-change material 340. The high reset currents may lead to greater uniformity and less differentiation of the temperature profile over the area of contact. The higher current density resulting from higher reset amplitude may simply extend the lateral distance over which control of the structural characteristics of phase-change material 340 would occur to a position beyond the dimensions of the opening in dielectric material 330 in which phase-change material 340 resides so that the thermal and electric environment across the lateral dimensions of phase-change material 340 are sufficiently uniform to yield a result analogous to that described in Example 1 hereinabove. In this view, the higher reset amplitudes of this example may produce more gradual resistance response curves in larger diameter devices.

The results of this example show that the sensitivity of the resistance response curve of a phase-change device can be controlled with a programming parameter. In particular, use of reset pulse width as a programming variable has been demonstrated to soften the resistance response curve to achieve a more controlled evolution of device resistance.

In the device of Example 1, the lateral resistivity of lower electrode 130 was too low to permit the degree of control over the distribution of thermal energy demonstrated in this example. The low lateral resistivity of lower electrode 130 leads to rapid lateral dissipation of thermal energy and rapid attainment of a uniform, thermally equilibrated interface of lower electrode 130 with phase-change material 160. The low lateral resistivity of lower electrode 130 further leads to a rapid equilibration of electrical current within lower electrode 130 so that the current density passing through phase-change material 160 is nearly uniform over a horizontal cross-section of phase-change material 160. As a result, it is difficult to achieve a differentiation in the relative proportions of crystalline and amorphous phases in directions lateral to current flow.

In the device of Example 2, the lateral resistivity of lower electrode 215 was too high to permit the degree of control over the distribution of thermal energy demonstrated in this example. The high lateral resistivity of lower electrode 215 significantly inhibited both lateral dissipation of thermal energy and lateral current flow. The thermal energy produced by Joule heating and current flow were effectively confined to the narrow conductive pathway formed during conditioning of lower electrode 215. The behavior within the narrow conductive pathway was similar to that of lower electrode 130 in device 100 of Example 1. The concentration of thermal energy to a confined region of lower electrode 215 precludes the lateral management of thermal energy afforded by the instant invention and prevents the degree of control over the relative proportions of crystalline and amorphous phase regions over the cross-section of the phase-change material needed to achieve the multilevel benefits demonstrated in this example.

While not wishing to be bound by theory, the instant inventors offer the following observations concerning the origin of the programming benefits achieved with this invention. The observations are intended to aid the public in understanding the invention by providing a conceptual or heuristic model of at least some of the phenomena underlying the effectiveness of pulse width as a programming parameter in the context of the instant invention. The discussion is intended to illuminate the invention and is not to be construed as a limitation thereof. Additional phenomena not described herein may also contribute to the behavior observed in the examples described hereinabove.

The flow of electric current through the lower electrode influences the structure of the phase-change material by establishing a particular distribution of thermal energy therein. The distribution of thermal energy in turn dictates the temperature profile within the phase change material. Of particular importance in controlling the relative proportions and spatial arrangement of crystalline and amorphous phase regions in the phase-change material is control over the local temperatures within the phase-change material relative to the crystallization and melting temperatures.

When the width of a programming pulse is increased, additional electrical and thermal energy is provided to the lower electrode. This additional energy will dissipate through two primary competing channels. First, the energy can dissipate in the primary direction of current flow and be transferred directly from the lower electrode to the phase-change material. This channel may be referred to herein as a longitudinal channel of energy dissipation. Second, the energy can dissipate lateral to the primary direction of current flow and be transferred radially within the lower electrode before being transferred to the phase-change material. This channel may be referred to herein as a lateral channel of energy dissipation.

In broad terms, the temperature profile established within the phase-change material is controlled by the competition between the longitudinal and lateral dissipation channels. When the lateral resistivity of the lower electrode is high, the longitudinal channel dominates and most of the additional energy supplied by an increased pulse width is transferred directly to the phase-change material without appreciable lateral transport. In this situation, as occurs in Example 2 hereinabove, the effective area of contact of the lower electrode with the phase-change material is controlled by the cross-section of the longitudinal channel of thermal and electrical energy transport. As pulse width increases, additional energy is delivered through the longitudinal channel, but the high lateral resistivity precludes an expansion of the effective area of energy transport from the lower electrode to the phase-change material. As a result, the distribution of thermal energy within phase-change material is governed primarily by the characteristics (such as thermal conductivity, resistivity, heat capacity) of the phase-change material. The lower electrode is in essence a passive element that provides no meaningful mechanism for influencing the temperature profile within the phase-change material.

As the lateral resistivity of the lower electrode decreases, the lateral channel of thermal and electrical energy transport becomes more important and new opportunities for using pulse width to control the temperature profile within the phase-change material arise. The availability of a viable lateral channel, in conjunction with pulse width modulation, enables the lower electrode to assume a more active role in controlling the distribution of thermal and electrical energy transferred to the phase-change material. As indicated above, when no lateral channel of energy dissipation is available, the added energy accompanying an increased pulse width is delivered directly to the phase-change material and the distribution of thermal energy within the phase-change material is dominated by processes within the phase-change material. In this situation, the area over which energy is transferred from the lower electrode to the phase-change material is fixed and the rate of transfer of energy is limited by processes internal to the phase-change material. The excess energy accompanying longer pulses accumulates and remains stored in the lower electrode for so long as it takes for energy to redistribute itself through internal processes occurring within the phase-change material.

If a lateral channel of dissipation is present, however, the excess energy supplied by longer pulses may be redistributed laterally within the lower electrode before transferring to the phase-change material. The overall result is a spreading or lateral transport of the electrical current and its accompanying thermal energy over a larger effective area before transfer to the phase-change material occurs. The opportunity for using pulse width to control the temperature profile within the phase-change material arises because the extent to which lateral spreading occurs is a function of pulse width. The extent of lateral dissipation depends on the relative rates of longitudinal and lateral energy transport. At short pulse widths, the relative rates are controlled by the intrinsic characteristics of the lower electrode. As the pulse width increases and more energy accumulates at the interface with the phase-change material, however, the capacity of the phase-change material to receive the energy becomes increasingly important and may inhibit the longitudinal channel of energy transport.

One factor contributing to the inhibition is the heating of the phase-change material at the point of transfer of electrical energy to the phase-change material. As the temperature of the phase-change material increases and becomes more similar to the temperature of the lower electrode, the driving force (temperature gradient) for thermal transfer from the lower electrode to the phase-change material decreases. Since the thermal conductivity of the lower electrode is higher than the thermal conductivity of the phase-change material, lateral thermal transfer within the lower electrode becomes increasingly more important as the pulse width increases. The net result is that longer pulses lead to greater penetration of thermal energy in lateral directions and the degree of lateral penetration can be systematically controlled using pulse width as a programming parameter.

Lateral control over the distribution of electric current and thermal energy in the lower electrode provides a degree of freedom for controlling the temperature profile within the phase-change material. By controlling the lateral dissipation of electrical and thermal energy, the temperature profile of the lower electrode at the interface with the phase-change material can be controlled. The lateral area, for example, over which the lower electrode is heated to a temperature of at least the melting temperature can be controlled and such control influences the extent to which amorphous phase regions form in the phase-change material. Similarly, control over the lateral area of the lower electrode over which the temperature is maintained between the crystallization and melting temperatures influences the extent to which crystallization occurs in the phase-change material.

If lateral dissipation is too efficient at a particular current level, pulse width becomes a less effective programming variable for controlling the temperature profile within the phase-change material. This is because it becomes more difficult to use pulse width as a means to establish a temperature profile in the lower electrode in which a spatial differentiation of regions having temperatures below the crystallization temperature, between the crystallization temperature and melting temperature, and above the melting temperature occur within the cross-sectional dimension of the interface of the lower electrode with the phase-change material. Efficient lateral dissipation has a tendency to homogenize the temperature profile of the lower electrode and as the temperature profile becomes more uniform over the length scale of the interfacial area of contact to the phase-change material, it becomes more difficult to differentially program different portions of the phase-change material. Instead, as in Example 1, the application of electrical pulses tends to produce more spatially uniform structural transformations of the phase-change material.

If lateral dissipation is not efficient enough at a particular current level, pulse width also becomes a less effective programming variable for controlling the temperature profile within the phase-change material. As discussed in Example 2 hereinabove, high lateral resistance confines the energy associated with a programming pulse and prevents dissipation of the (electrical or thermal) energy of the pulse in lateral directions. As a result, the lateral area over which the energy of the pulse extends is controlled by the electrode material and relatively insensitive to pulse width.

The resistivity of the lower electrode governs the efficiency of lateral dissipation of electrical and thermal energy. (More accurately, the lateral resistivity is the governing factor. Since most electrode materials are isotropic, however, the resistivity is uniform in all directions.) The examples presented hereinabove indicate that the efficiency of lateral dissipation needed to achieve the controlled programming benefits of the instant invention occurs over an optimal range. If the efficiency of lateral dissipation is too high or too low, pulse width becomes a less effective programming variable for systematically and incrementally controlling the structural state of the phase-change material as is desired for multilevel operation. In one embodiment, an effective degree of lateral dissipation occurs when the resistivity of the lower electrode is between 1 mΩ-cm and 100 mΩ-cm. In another embodiment, the resistivity of the lower electrode is between 1 mΩ-cm and 20 mΩ-cm. In still another embodiment, the resistivity of the lower electrode is between 2 mΩ-cm and 10 mΩ-cm. In a further embodiment, the resistivity of the lower electrode is between 3 mΩ-cm and 7 mΩ-cm.

The chalcogenide materials generally include one or more elements from column VI of the periodic table (the chalcogen elements) and optionally one or more chemical modifiers from columns III, IV or V. One or more of S, Se, and Te are the most common chalcogen elements included in a chalcogenide phase-change material. The chalcogen elements are characterized by divalent bonding and the presence of lone pair electrons. The divalent bonding leads to the formation of chain and ring structures upon combining chalcogen elements to form chalcogenide materials and the lone pair electrons provide a source of electrons for forming a conducting filament. Suitable modifiers include one or more of trivalent and tetravalent modifying elements such as As, Ge, Ga, Si, Sn, Pb, Al, Sb, In, and Bi. Transition metals such as Cu, Ni, Zn, Ag, and Cd may also be used as modifiers. A preferred chalcogenide composition includes one or more chalcogenide elements along with one or more trivalent or tetravalent modifiers and/or one or more transition metal modifiers. Materials that include Ge, Sb, and/or Te, such as Ge₂Sb₂Te₅, are examples of chalcogenide materials in accordance with the instant invention. Other examples of phase-change materials include, but are not limited to, GaSb, InSb, InSe, Sb₂Te₃, GeTe, and other ternary Ge—Sb—Te compositions, In₂Sb₂Te₅ and other ternary In—Sb—Te compositions, ternary GaSeTe compositions, TAG and other ternary Te—As—Ge compositions, GaSeTe, SnSb₂Tc₄, quaternary Ag—In—Sb—Te compositions, quaternary Ge—Sn—Sb—Te compositions, quaternary Ge—Sb—Se—Te compositions, and Te₈₁Ge₁₅Sb₂S₂ and other quaternary Te—Ge—Sb—S compositions.

Chalcogenide phase-change materials have been discussed in U.S. Pat. Nos. 5,166,758; 5,296,716; 5,534,711; 5,536,947; 5,543,737; 5,596,522; 5,694,146; 5,757,446; and 6,087,674; the disclosures of which are hereby incorporated by reference.

The present invention has been particularly shown and described with reference to the foregoing embodiments, which are merely illustrative of the best modes for carrying out the invention. It should be understood by those skilled in the art that various alternatives to the embodiments of the invention described herein may be employed in practicing the invention without departing from the spirit and scope of the invention as defined in the following claims. The embodiments should be understood to include all novel and non-obvious combinations of elements described herein, and claims may be presented in this or a later application to any novel and non-obvious combination of these elements. Moreover, the foregoing embodiments are illustrative, and no single feature or element is essential to all possible combinations that may be claimed in this or a later application.

With regard to the processes, methods, heuristics, etc. described herein, it should be understood that although the steps of such processes, etc. have been described as occurring according to a certain ordered sequence, such processes could be practiced with the described steps performed in an order other than the order described herein. It further should be understood that certain steps could be performed simultaneously, that other steps could be added, or that certain steps described herein could be omitted. In other words, the descriptions of processes described herein are provided for illustrating certain embodiments and should in no way be construed to limit the claimed invention.

Accordingly, it is to be understood that the above description is intended to be illustrative and not restrictive. Many embodiments and applications other than the examples provided would be apparent to those of skill in the art upon reading the above description. The scope of the invention should be determined, not with reference to the above description, but should instead be determined with reference to the appended claims, along with the full scope of equivalents to which such claims are entitled. It is anticipated and intended that future developments will occur in the arts discussed herein, and that the disclosed systems and methods will be incorporated into such future embodiments. In sum, it should be understood that the invention is capable of modification and variation and is limited only by the following claims.

All terms used in the claims are intended to be given their broadest reasonable constructions and their ordinary meanings as understood by those skilled in the art unless an explicit indication to the contrary is made herein. In particular, use of the singular articles such as “a,” “the,” “said,” etc. should be read to recite one or more of the indicated elements unless a claim recites an explicit limitation to the contrary.

We claim:

1. A method of programming an electronic device comprising:
providing a first electrode;
providing a phase-change material in electrical communication with said first electrode, said phase-change material having a plurality of programming states, said programming states including a set state with a set resistance, a reset state with a reset resistance, and one or more intermediate states with a resistance between said set resistance and said reset resistance;
providing a second electrode in electrical communication with said phase-change material;
applying a first electrical pulse between said first electrode and said second electrode, said first electrical pulse having a first amplitude and a first duration, said first electrical pulse transforming said phase-change material to a first programming state; and
applying a second electrical pulse between said first electrode and said second electrode, said second electrical pulse having a second amplitude and a second duration, said second duration differing from said first duration, said second electrical pulse transforming said phase-change material to a second programming state;
wherein said first programming state or said second programming state is one of said intermediate states.

2. The method of claim 1, wherein said first electrode comprises an annealed conductive material.

3. The method of claim 2, wherein said first electrode comprises nitrogen.

4. The method of claim 3, wherein said first electrode further comprises a metal or silicon.

5. The method of claim 2, wherein said second electrode comprises an annealed conductive material.

6. The method of claim 1, wherein said first electrode comprises a material selected from the group consisting of TiAlN, TiSiN, TiW, TiN, MoN, and nitrogenated carbon.

7. The method of claim 1, wherein the resistivity of said first electrode is between 1 mΩ-cm and 100 mΩ-cm.

8. The method of claim 1, wherein the resistivity of said first electrode is between 1 mΩ-cm and 20 mΩ-cm.

9. The method of claim 1, wherein the resistivity of said first electrode is between 2 mΩ-cm and 10 mΩ-cm.

10. The method of claim 1, wherein the resistivity of said first electrode is between 3 mΩ-cm and 7 mΩ-cm.

11. The method of claim 1, wherein said phase-change material comprises a chalcogen element.

12. The method of claim 11, wherein said phase-change material further comprises Ge, In, or Sb.

13. The method of claim 1, wherein said first amplitude equals said second amplitude.

14. The method of claim 1, wherein said first programming state or said second programming state is said set state.

15. The method of claim 1, wherein said first programming state or said second programming state is said reset state.

16. The method of claim 1, wherein said first programming state is a first intermediate state and said second programming state is a second intermediate state.

17. The method of claim 1, wherein said phase-change material comprises amorphous regions and crystalline regions, said first programming state having a first volume fraction of said amorphous regions, said second programming state having a second volume fraction of said amorphous region.

18. The method of claim 1, wherein said first electrical pulse produces a first temperature profile at the interface of said first electrode and said phase-change material and said second electrical pulse produces a second temperature profile at the interface of said first electrode and said phase-change material.

19. The method of claim 18, wherein said first temperature profile includes a first area over which the temperature of said phase-change material at said interface is greater than or equal to the crystallization temperature of said phase-change material and said second temperature profile includes a second area over which the temperature of said phase-change material at said interface is greater than or equal to the crystallization temperature of said phase-change material, said second area differing from said first area.

20. The method of claim 19, wherein said first temperature profile further includes a third area over which the temperature of said phase-change material at said interface is greater than or equal to the melting temperature of said phase-change material and said second temperature profile includes a fourth area over which the temperature of said phase-change material at said interface is greater than or equal to the melting temperature of said phase-change material, said fourth area differing from said third area.
